(19) United States
(12) Patent Application Publication
(10) Pub. No.: US 2007/0131649 A1
(43) Pub. Date: Jun. 14, 2007

(54) ETCHING METHOD

(76) Inventors: Hong-Long Chang, Hsinchu (TW); Kai-Mu Hsiao, Hsinchu City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/308,656

(22) Filed: Apr. 19, 2006

(30) Foreign Application Priority Data
Dec. 8, 2005 (TW) 94143344

(51) Int. Cl. H01B 13/00; H01L 21/461; C03C 25/68; B44C 1/22; H01L 21/302

(52) U.S. Cl. 216/58; 216/17; 438/706; 216/41; 438/734

(57) ABSTRACT

The invention is directed to an etching method. The etching method comprises steps of providing a material layer having a patterned hard mask layer formed thereon and then performing a first dry etching process by using the patterned hard mask layer as a mask, wherein a first power mode of the first dry etching process is a pulse mode and the first dry etching process is performed for a first process time. A second dry etching process is performed by using the patterned hard mask layer as a mask, wherein a second power mode of the second dry etching process is a continued wave mode and the second dry etching process is performed for a second process time, and the ratio of the first process time to the second process time is about 0.1˜2.0.

### CROSS-REFERENCE TO RELATED APPLICATION

This application claims the priority benefit of Taiwan application ser. no. 94143344, filed on Dec. 8, 2005. All disclosure of the Taiwan application is incorporated herein by reference.

### BACKGROUND OF THE INVENTION

1. Field of Invention

The present invention relates to an etching method. More particularly, the present invention relates to a dry etching process.

2. Description of Related Art

Currently, the etching processes widely used in the semiconductor industry can be classified into two types. One is the wet etching technology and the other is the dry etching technology. Since the dry etching technology has the advantage about performing the anisotropic etching, it becomes an essential technology in the integrated circuit process.

Among the dry etching processes, there is a so-called plasma etching technology. In the plasma etching technology, the molecules of the reactant gas are ionized to be reactive ions with respect to the thin film material by the plasma. Then, the thin film exposed under the plasma is converted into a volatile product through the chemical reaction between the ions and the thin film. Then, the volatile product is vacuumed out.

When a portion of the material layer exposed by the patterned hard mask layer is removed to form characteristic structures, such as the gate electrode or the deep trench in the material layer, by etching with the patterned hard mask layer as an etching mask, the power mode of the etching tool is set to be the continued wave mode in the conventional etching technology. However, under the continued wave power mode, the etching selective ratio is relatively low. Therefore, as the thickness of the etched portion of the material layer is large, the patterned hard mask layer is exhausted before the etching process is accomplished. Accordingly, the resultant pattern formed in the material layer dose not meet the requirements of the desired characteristic structure. Taking the formation of deep trench as an example, before the depth of the deep trench reaches the predetermined value, the patterned hard mask layer is exhausted during the etching process so that the etching process is terminated and the deep trench is not deep enough.

In order to solve the problem that the patterned hard mask layer on the material layer is exhausted before the predetermined characteristic structure is formed in the material layer by the dry etching process, the power mode of the etching tool is set to be the pulse mode in the conventional technology for increasing the etching selective ratio. Although the etching selective ratio is increased and the patterned hard mask layer is prevented from being over etched under the pulse power mode, the ion bombardment energy is not enough. Accordingly, the etched amount of the material layer does not meet the predetermined amount and the profile of the structure does not meet the standard of the characteristic structure. For the deep trench with the relatively high aspect ratio, the problem mentioned above is getting serious.

### SUMMARY OF THE INVENTION

Accordingly, at least one objective of the present invention is to provide an etching method capable of improving the etching selectivity and increasing the ion bombardment energy.

At least another objective of the present invention is to provide a method for forming a deep trench with relatively large depth.

To achieve these and other advantages and in accordance with the purpose of the invention, as embodied and broadly described herein, the invention provides an etching method. The etching method comprises steps of providing a material layer having a patterned hard mask layer formed thereon and then performing a first dry etching process by using the patterned hard mask layer as a mask, wherein a first power mode of the first dry etching process is a pulse mode and the first dry etching process is performed for a first process time. A second dry etching process is performed by using the patterned hard mask layer as a mask, wherein a second power mode of the second dry etching process is a continued wave mode and the second dry etching process is performed for a second process time, and the ratio of the first process time to the second process time is about 0.1˜2.0.

The present invention also provides a method for forming a deep trench. The method comprises steps of providing a substrate having a patterned hard mask layer formed thereon and then performing a first dry etching process by using the patterned hard mask layer as a mask, wherein a first power mode of the first dry etching process is a pulse mode and the first dry etching process is performed for a first process time. A second dry etching process is performed by using the patterned hard mask layer as a mask, wherein a second power mode of the second dry etching process is a continued wave mode and the second dry etching process is performed for a second process time, and the ratio of the first process time to the second process time is about 0.1˜2.0.

The present invention further provides an etching method. The etching method comprises steps of providing a material layer having a patterned hard mask layer formed thereon and then performing a first dry etching process to form a first predetermined structure by using the patterned hard mask layer as a mask, wherein a first power mode of the first dry etching process is a pulse mode and the first dry etching process is performed for a first process time. A second dry etching process is performed on the first predetermined structure to form a second predetermined structure by using the patterned hard mask layer as a mask, wherein a second power mode of the second dry etching process is a continued wave mode and the second dry etching process is performed for a second process time.

In the present invention, since the power mode adopted in the first dry etching process is the pulse mode, the etching selectivity of the first dry etching process is relatively good. Therefore, the consumption rate of the patterned hard mask layer is decreased. Hence, the patterned hard mask layer can be prevented from being exhausted before the etching process is accomplished.

Moreover, since power mode adopted in the second dry etching process is the continued wave mode, the ion bombardment is relatively strong. Accordingly, even large etched amount of the material layer can be removed successfully to form the predetermined characteristic structure.

Furthermore, in the method for forming the deep trench provided by the present invention, a two-step etching process is applied. The first etching process is performed with a pulse power mode first and then the second etching process is performed with a continued wave power mode. Therefore, the depth of the deep trench is relatively large.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a flow chart schematically illustrating an etching method according to one embodiment of the invention.

FIG. 2 is an output signal timing diagram of a power generator according to one embodiment of the invention.

FIGS. 3A through 3B are cross-sectional views illustrating process procedure for forming a deep trench according to an embodiment of the present invention.

### DESCRIPTION OF THE PREFERRED EMBODIMENTS

FIG. 1 is a flow chart schematically illustrating an etching method according to one embodiment of the invention.

As shown in FIG. 1, in the step S102, a material layer having a patterned hard mask layer formed thereon is provided. The patterned hard mask layer can be, for example but not limited to, made of silicon nitride or other proper material. The material layer can be, for example but not limited to, made of monocrystalline silicon, epi silicon, polysilicon or amorphous silicon. Or, the material of the material layer can be, for example, dielectric material such as silicon oxide, silicon nitride or the material accommodating to the characteristic structure to be formed. That is, people skilled in the art can easily apply various materials for the material layer to accommodate the characteristic structure while applying the present invention. For example, if the characteristic structure is a deep trench of the deep trench type capacitor, the material layer can be a monocrystalline silicon substrate. If the characteristic structure is a contact opening, the material layer can be a dielectric layer made of silicon oxide or silicon nitride. If the characteristic structure is a gate electrode, the material layer can be a doped polysilicon layer.

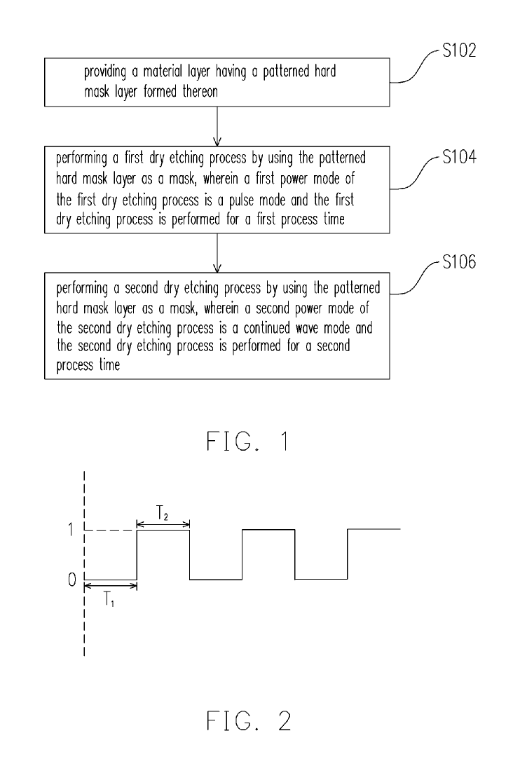

Then, in the step S104, by using the patterned hard mask layer as a mask, a first dry etching process is performed on the material layer, wherein the power mode of the power generator is a pulse mode and the first dry etching process is performed for a first process time. The frequency of the pulse of the pulse mode is about 1 Hz˜50 KHz. Preferably, the frequency of the pulse of the pulse mode is about 10 Hz˜30 KHz. Thereafter, FIG. 2 is used to describe the definitions of the duty cycle and the frequency of the pulse in the specification.

FIG. 2 is an output signal timing diagram of a power generator according to one embodiment of the invention.

As shown in FIG. 2, the signal as the radio frequency (RF) power is on is set to be logic 1 and the signal as the radio frequency power is off is set to be logic 0. The duration T₂ indicates the turned-on duration of the radio frequency power and duration T₁ indicates the turned-off duration of the radio frequency power. In the present invention, the duty cycle and the frequency of the pulse wave are defined as following:

duty cycle=T₂ /(T₁+T₂); and

frequency of the pulse wave=1/T₁.

Then, as shown in FIG. 1, in the step S106, by using the patterned hard mask layer as a mask, a second dry etching process is performed on the material layer, wherein the power mode of the power generator is a continued wave mode and the second dry etching process is performed for a second process time. The time for performing the first dry etching process and the second dry etching process is determined by the profile (or depth) of the structure to be formed. The first process time can be either as same as or different from the second process time.

Moreover, the first dry etching process and the second dry etching process can be, for example but not limited to, performed by the reactive ion etch reactor, magnetic-enhanced reactive ion etch (MERIE) reactor or inductive coupled plasma (ICP) reactor.

Since the etching method in the present invention is a two-step etching process and the power mode adopted in the first dry etching process is the pulse mode, the etching selectivity of the etching method is better and the consumption rate of the patterned hard mask layer is low. Therefore, the problem that the patterned hard mask layer is exhausted before the etching process is solved. Furthermore, the power mode in the second dry etching process is the continued wave mode so that the plasma ions possess stronger ion bombardment ability. Hence, even under the circumstance that the etched thickness of the material layer is large, a predetermined etched amount of the material layer can be successfully removed to form the predetermined characteristic structure.

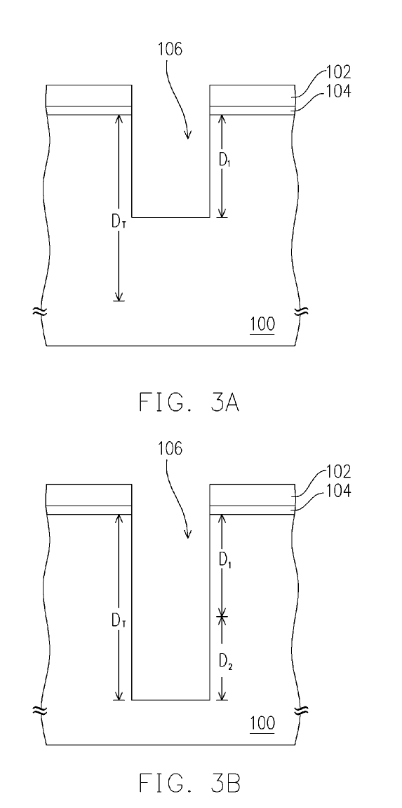

FIGS. 3A through 3B are cross-sectional views illustrating process procedure for forming a deep trench according to an embodiment of the present invention.

As shown in FIG. 3A, a substrate 100 having a patterned hard mask layer 102 formed thereon is provided. The substrate 100 can be, for example but not limited to, a monocrystalline silicon substrate. The patterned hard mask layer 102 can be, for example but not limited to, made of silicon nitride. Moreover, a pad oxide layer 104 can be formed under the patterned hard mask layer 102.

Then, the substrate 100 is etched to form a deep trench with a predetermined depth D_{T}.

Thereafter, by using the hard mask layer 102 as a mask, a first dry etching process is performed on the substrate 100, wherein the power mode adopted in the first dry etching process is a pulse mode and the first dry etching process is performed for a first process time. The thickness of a portion of the substrate etched away by the first dry etching process is denoted as D₁ so that the depth of the deep trench 106 in the substrate 100 is D₁. The duty cycle of the pulse mode is about 1%˜99% and the frequency of the pulse of the pulse mode is about 1 Hz˜50 KHz. Preferably, the frequency of the pulse of the pulse mode is about 10 Hz˜30 KHz.

As shown in FIG. 3B, by using the hard mask layer 102 as a mask, a second dry etching process is performed on the substrate 100, wherein the power mode adopted in the second dry etching process is a continued wave mode and the second dry etching process is performed for a second process time. The thickness of a portion of the substrate etched away by the second dry etching process is denoted as D₂ so that the depth of the deep trench 106 in the substrate 100 meets the predetermined depth D_{T}. In one embodiment, if the predetermined depth D_{T} is about 6˜7 micron meters, the ratio of the first process time to the second process time is about 0.1˜2.0. Preferably, the ratio of the first process time to the second process time is about 1.0˜1.5.

In this embodiment, the deep trench 106 is formed by the two-step etching process. In the first etching process, the pulse power mode is adopted so that the first etching process possesses relatively good etching selectivity. Thus, the consumption rate of the patterned hard mask layer 102 is decreased so as to define the width of the deep trench 106 more precisely. In the second etching process, the continued wave power mode is adopted so that plasma ions possess relatively strong ion bombardment ability. Accordingly, the deep trench 106 with a sufficient depth is formed. Hence, by adjusting the process parameters, such as time of the two-step etching process, a trench with a predetermined aspect ratio (a ratio of depth to width) can be formed.

Additionally, the aforementioned method for forming the deep trench in the substrate is used to describe one of the applications of the present invention. However, the present invention is not limited to the embodiment mentioned above. The two-step etching process can be, of course, applied to form other characteristic structures. For example, the present invention can be applied to form a contact hole or a gate line opening denoted by 106 in the substrate denoted by 100.

Altogether, the present invention possesses the advantages as following: (1) the method is capable of balancing the etching selective ratio and the ion bombardment energy so as to form the predetermined characteristic structure; (2) the etching method is capable of preventing the etching hard mask layer from being exhausted before the etching process is accomplished; and (3) the method is capable of forming a deep trench, a hole or an opening with a relatively large depth.

It will be apparent to those skilled in the art that various modifications and variations can be made to the structure of the present invention without departing from the scope or spirit of the invention. In view of the foregoing descriptions, it is intended that the present invention covers modifications and variations of this invention if they fall within the scope of the following claims and their equivalents.

What is claimed is:

1. An etching method comprising:
providing a material layer having a patterned hard mask layer formed thereon;
performing a first dry etching process by using the patterned hard mask layer as a mask, wherein a first power mode of the first dry etching process is a pulse mode and the first dry etching process is performed for a first process time; and
performing a second dry etching process by using the patterned hard mask layer as a mask, wherein a second power mode of the second dry etching process is a continued wave mode and the second dry etching process is performed for a second process time, and a ratio of the first process time to the second process time is about 0.1˜2.0.

2. The etching method of claim 1, wherein a duty cycle of the pulse mode is about 1%˜99%.

3. The etching method of claim 1, wherein a frequency of pulse of the pulse mode is about 1 Hz˜50 KHz.

4. The etching method of claim 1, wherein a material of the material layer is selected from a group consisting of monocrystalline silicon, epi silicon, polysilicon, and amorphous silicon.

5. The etching method of claim 1, wherein a material of the material layer is dielectric material.

6. The etching method of claim 5, wherein the dielectric material includes silicon oxide.

7. The etching method of claim 5, wherein the patterned hard mask layer is made of silicon nitride.

8. A method for forming a deep trench comprising:
providing a substrate having a patterned hard mask layer formed thereon;
performing a first dry etching process by using the patterned hard mask layer as a mask, wherein a first power mode of the first dry etching process is a pulse mode and the first dry etching process is performed for a first process time; and
performing a second dry etching process by using the patterned hard mask layer as a mask, wherein a second power mode of the second dry etching process is a continued wave mode and the second dry etching process is performed for a second process time, and a ratio of the first process time to the second process time is about 0.1˜2.0.

9. The method of claim 8, wherein a duty cycle of the pulse mode is about 1%˜99%.

10. The method of claim 8, wherein a frequency of pulse of the pulse mode is about 1 Hz˜50KHz.

11. The method of claim 8, wherein the substrate includes a silicon substrate.

12. The method of claim 8, wherein the patterned hard mask layer is made of silicon nitride.

13. An etching method comprising:
providing a material layer having a patterned hard mask layer formed thereon;
performing a first dry etching process to form a first predetermined structure by using the patterned hard mask layer as a mask, wherein a first power mode of the first dry etching process is a pulse mode and the first dry etching process is performed for a first process time; and
performing a second dry etching process on the first predetermined structure to form a second predetermined structure by using the patterned hard mask layer as a mask, wherein a second power mode of the second dry etching process is a continued wave mode and the second dry etching process is performed for a second process time.

14. The etching method of claim 13, wherein the first process time is different from the second process time.

15. The etching method of claim 13, wherein the first process time is as same as the second process time.

16. The etching method of claim 13, wherein a material of the material layer includes silicon.

17. The etching method of claim 13, wherein a material of the material layer includes dielectric material.

18. The etching method of claim 13, wherein the second predetermined structure is a trench, a contact hole or a gate line opening.
